(19) United States
(12) Patent Application Publication
(10) Pub. No.: US 2024/0204131 A1
(43) Pub. Date: Jun. 20, 2024

(54) LIGHT-EMITTING DEVICE AND MANUFACTURING METHOD THEREOF

(71) Applicant: EPISTAR CORPORATION, Hsinchu (TW)

(72) Inventors: Jan-Way CHIEN, Hsinchu (TW); Heng-Ying CHO, Hsinchu (TW); Wei-Ting CHANG, Hsinchu (TW)

(21) Appl. No.: 18/540,278

(22) Filed: Dec. 14, 2023

(30) Foreign Application Priority Data
Dec. 19, 2022 (TW) 111148644

(51) Int. Cl. H01L 33/00; H01L 33/38; H01L 33/44

(52) U.S. Cl. CPC H01L 33/0095; H01L 33/38; H01L 33/44; H01L 25/167

(57) ABSTRACT

A manufacturing method for a light-emitting device includes: forming a semiconductor stack; forming an electrode on the semiconductor stack, wherein the electrode includes a first top surface and a side surface; forming an insulating stack on the semiconductor stack and the electrode, wherein the insulating stack includes a plurality of first sub-layers with a first refractive index and a plurality of second sub-layers with a second refractive index alternately stacked; removing a portion of the insulating stack to expose the first top surface, leaving another portion of the insulating stack having a second top surface surrounding the first top surface, and a level of the second top surface is lower than or equal to that of the first upper surface; and forming an electrode pad on the insulating stack, wherein the electrode pad contacts the first top surface.

### CROSS-REFERENCE TO RELATED APPLICATIONS

This application claims priority to and the benefit of Taiwan Patent Application Number 111148644 filed on Dec. 19, 2022 and Taiwan Patent Application Number 112148652 filed on Dec. 14, 2023, and the entire contents of which are hereby incorporated by reference herein in their entireties.

### BACKGROUND

### Technical Field

The present application relates to a light-emitting device and manufacturing method thereof, and more specifically, to a light-emitting device having an insulating reflective structure and manufacturing method thereof.

### Description of the Related Art

Light-emitting diodes of solid-state lighting device have the characteristics of low power consumption, high brightness, high color rendering index (CRI) and compact size. Thus, light-emitting diodes have been widely used in lighting and display apparatus. For example, light-emitting diodes can replace the pixels of conventional liquid crystal display and achieve high quality display image. While the light-emitting diodes are incorporated into various optoelectronic products whose volumes are getting smaller, a smaller size of the light-emitting diode with qualified photoelectric characteristics and manufacturing yield is also desired.

### SUMMARY OF THE DISCLOSURE

A manufacturing method for a light-emitting device includes: forming a semiconductor stack: forming an electrode on the semiconductor stack, wherein the electrode includes a first top surface and a side surface; forming an insulating stack on the semiconductor stack and the electrode, wherein the insulating stack includes a plurality of first sub-layers with a first refractive index and a plurality of second sub-layers with a second refractive index alternately stacked: removing a portion of the insulating stack to expose the first top surface, leaving another portion of the insulating stack having a second top surface surrounding the first top surface, and a level of the second top surface is lower than or equal to that of the first upper surface; and forming an electrode pad on the insulating stack, wherein the electrode pad contacts the first top surface.

A light-emitting device includes: a semiconductor stack: an electrode formed on the semiconductor stack, including a first top surface and a side surface; an insulating stack covering the semiconductor stack and the side surface, including a plurality of first sub-layers with a first refractive index and a plurality of second sub-layers with a second refractive index alternately stacked; and an electrode pad formed on the insulating stack, connecting to the first top surface; wherein the insulating stack includes a second top surface surrounding the first top surface and having a level lower than or equal to that of the first top surface.

### BRIEF DESCRIPTION OF THE DRAWINGS

FIGS. 1A to 1H show a manufacturing method for a light-emitting device 1 in accordance with one embodiment of the present application.

FIGS. 2A and 2B show detailed structures of an insulating stack in accordance with different embodiments of the present application.

FIGS. 3A to 3B show a manufacturing method for a light-emitting device 1′ in accordance with another embodiment of the present application.

FIGS. 4A to 4C show a manufacturing method for a light-emitting device 2 in accordance with another embodiment of the present application.

FIGS. 5A to 5F show a manufacturing method for a light-emitting device 3 in accordance with another embodiment of the present application.

FIGS. 6A to 6C show a manufacturing method for a light-emitting device 4 in accordance with another embodiment of the present application.

FIG. 7 shows a cross-sectional view of a light-emitting device 5 in accordance with another embodiment of the present application.

FIGS. 8A to 8C show a manufacturing method for a light-emitting device 6 in accordance with another embodiment of the present application.

FIGS. 9A to 9C show a manufacturing method for a light-emitting device 7 in accordance with another embodiment of the present application.

FIGS. 10A to 10C show a manufacturing method for a light-emitting device 3 in accordance with another embodiment of the present application.

FIG. 11 shows a light-emitting module 100 in accordance with an embodiment of the present application.

### DETAILED DESCRIPTION

In order to make the description of the present application more detailed and complete, the description of the following embodiments can cooperate with the relevant illustrations. However, the examples shown below are used to illustrate the light-emitting device of the present application, and the present application is not limited to the following embodiments. The elements in the present application with the same or similar structure, function or nature are represented by the same label and people skilled in the art can understand them by the disclosure of the present application. Furthermore, for the for clarity and conciseness of the description, the details of the elements with the same symbols will not be repeated.

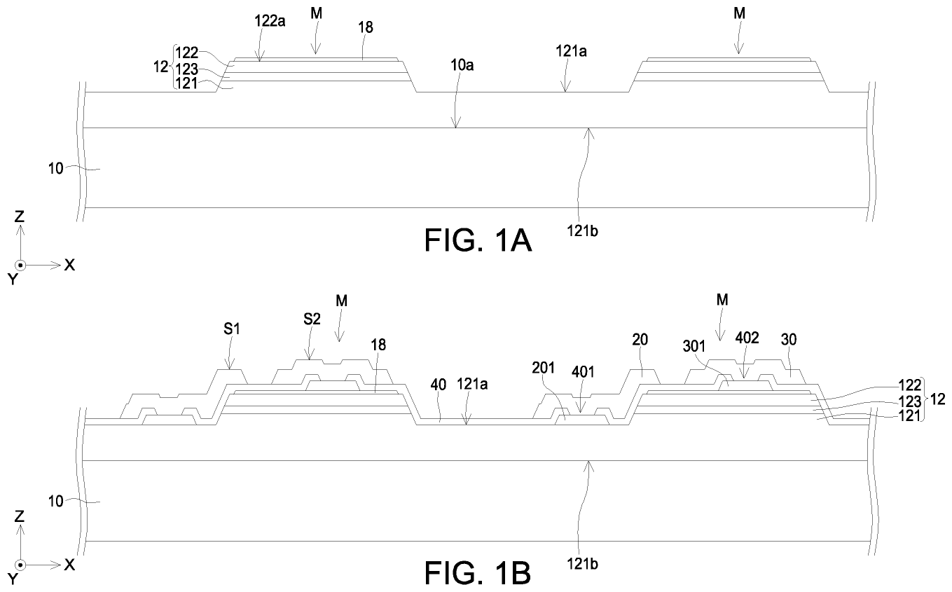

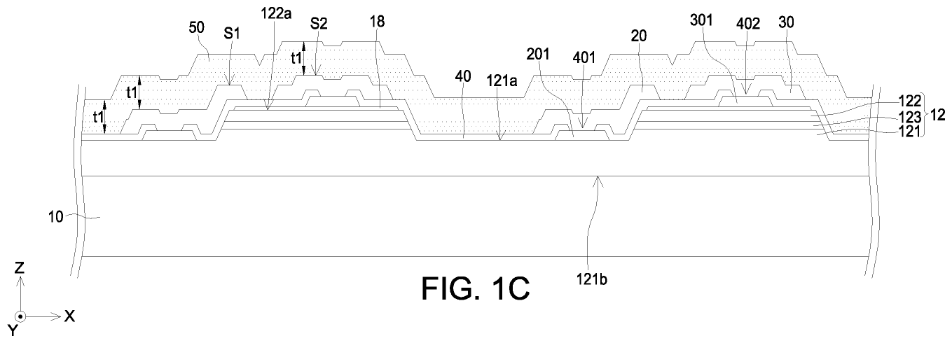

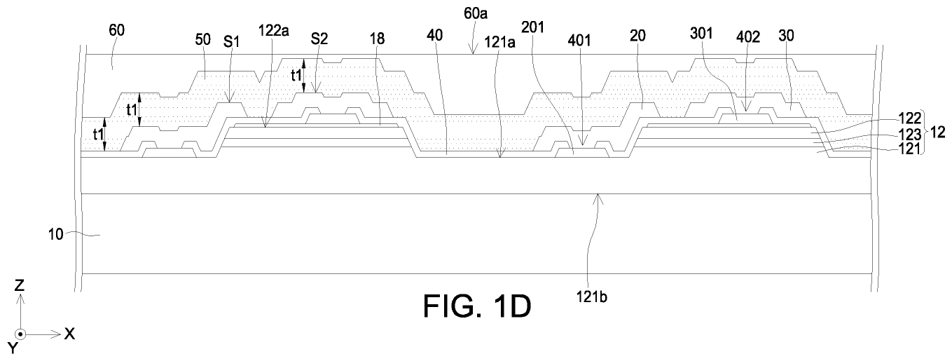

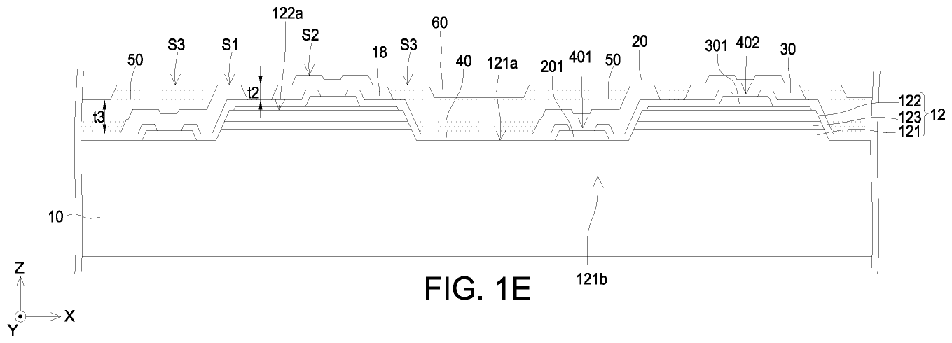

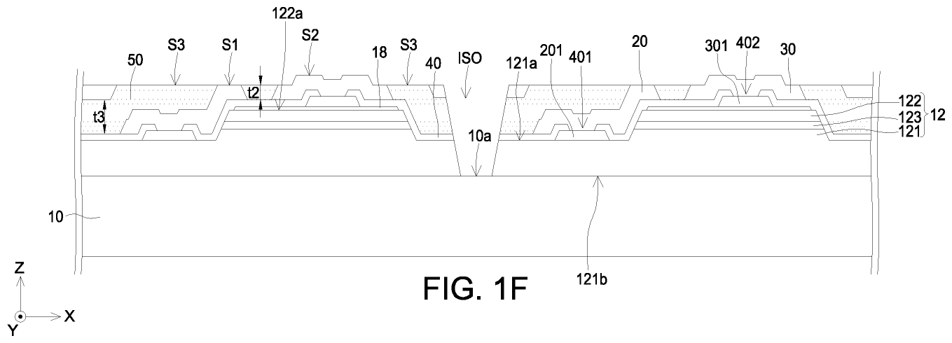

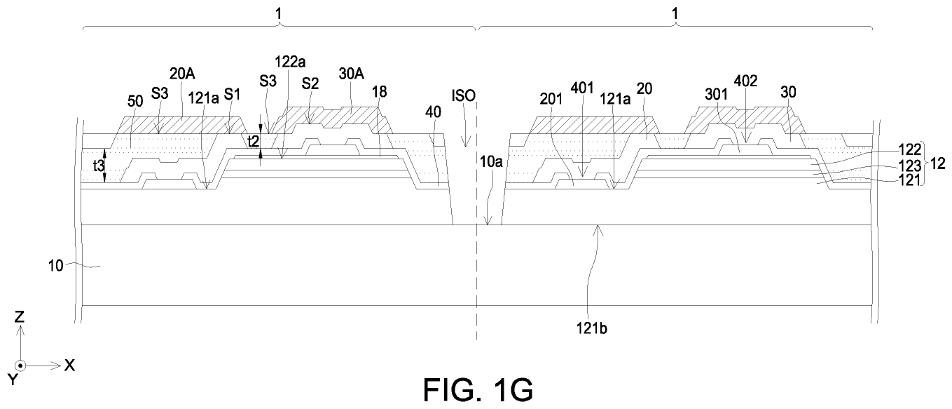

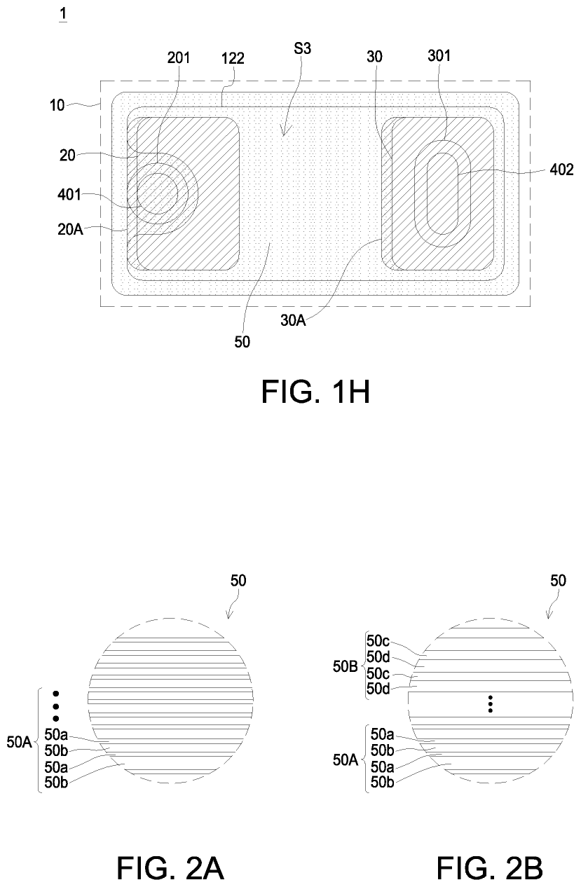

FIGS. 1A to 1G show a manufacturing method for a light-emitting device 1 in accordance with one embodiment of the present application. Firstly, as shown in FIG. 1A, a semiconductor stack 12 and a transparent conductive layer 18 are formed on a top surface 10a of a substrate 10. The semiconductor stack 12 includes a first semiconductor layer 121, an active region 123 and a second semiconductor layer 122. Next, parts of the active region 123 and the second semiconductor layer 122 are removed to form a plurality of mesas M and expose an upper surface 121a of the first semiconductor layer 121 around the mesas M. Then, the transparent conductive layer 18 is formed on the second semiconductor layer 122 of the plurality of mesas M. In another embodiment, after the semiconductor stack 10 and the transparent conductive layer 18 are formed on the top surface 10a of the substrate 10, parts of the active region 123, the second semiconductor layer 122 and the transparent conductive layer 18 are removed in a single process to expose the upper surface 121a of the first semiconductor layer 121, and the aforementioned mesas M and the transparent conductive layer 18 on the mesas are formed. In another embodiment (not shown), the transparent conductive layer 18 can be omitted.

The substrate 10 can be a growth substrate. The substrate 10 includes GaAs or GaP for growing AlGalnP based semiconductor thereon. The substrate 10 includes Al₂O₃, GaN, SiC or AlN for growing InGaN based or AlGaN based semiconductor thereon. In one embodiment, the substrate 10 can be a patterned substrate; that is, the substrate 10 includes patterned structures (not shown) on the top surface 10a. In one embodiment, the light generated from the semiconductor stack 12 can be refracted, reflected or scattered by the patterned structures, thereby increasing the brightness of the light-emitting device. In addition, the patterned structures lessen or suppress the dislocation caused by lattice mismatch between the substrate 10 and the semiconductor stack 12, thereby improving the epitaxy quality of the semiconductor stack 12. The material of the patterned structures can be different from or the same as that of the substrate 10. In the embodiment that the patterned structures and the substrate 10 include different materials, the patterned structure can include, for example, insulating material, such as silicon oxide, silicon nitride, or silicon oxynitride.

In an embodiment of the present application, the semiconductor stack 12 is formed on the substrate 10 by metal-organic chemical vapor deposition (MOCVD), molecular beam epitaxy (MBE), hydride vapor epitaxy (HVPE) or ion plating such as sputtering or evaporating.

In one embodiment, the semiconductor stack 12 further includes a buffer structure (not shown) between the first semiconductor layer 121 and the substrate 10. The buffer structure reduces the lattice mismatch and suppresses dislocation so as to improve the epitaxy quality. The material of the buffer structure includes GaN, AlGaN, or AlN. In an embodiment, the buffer structure includes a plurality of sub-layers (not shown) and the sub-layers include the same materials or different materials. In one embodiment, the buffer structure includes two sub-layers formed by different methods. For example, a first sub-layer of the buffer structure is grown by sputtering and a second sub-layer of the buffer structure is grown by MOCVD. In another embodiment, the buffer structure further includes a third sub-layer. The third sub-layer is grown by MOCVD, and the growth temperature of the second sub-layer is different from the growth temperature of the third sub-layer. In an embodiment, the first, second, and third sub-layers include the same material, such as AlN. In one embodiment, the first semiconductor layer 121 and the second semiconductor layer 122 are, for example, cladding layers or confinement layers. The first semiconductor layer 121 and the second semiconductor layer 122 have different conductivity types, different electrical properties, different polarities or different dopants for providing electrons or holes. For example, the first semiconductor layer 121 is composed of n-type semiconductor and the second semiconductor layer 122 is composed of p-type semiconductor. The active region 123 is formed between the first semiconductor layer 121 and the second semiconductor layer 122. When being driven by a current, electrons and holes are combined in the active region 123 to convert electrical energy into optical energy for illumination. The wavelength of the light generated by the light-emitting device 1 or by the semiconductor stack 12 can be adjusted by changing the physical properties and chemical composition of one or more layers in the semiconductor stack 12.

The material of the semiconductor stack 12 includes III-V compound semiconductor such as AlₓIn_{y}Ga_{(1-x-y)}N(i.e. AlInGaN base) or AlₓIn_{y}Ga_{(1-x-y)}P (i.e. AlInGaP base), where 0≤x, y≤1: x+y≤1. When the material of the semiconductor stack 12 includes AlInGaP based material, the semiconductor stack 12 emits red light having a wavelength between 610 nm and 650 nm or yellow light having a wavelength between 550 nm and 570 nm. When the material of the semiconductor stack 12 includes AlInGaN based material, the semiconductor stack 12 emits blue light or deep blue light having a wavelength between 400 nm and 490 nm, green light having a wavelength between 490 nm and 550 nm or UV light having a wavelength between 250 nm and 400 nm. The active region 123 can be a single hetero-structure (SH), a double hetero-structure (DH), a double-side double hetero-structure (DDH), or a multi-quantum well (MQW) structure. The material of the active region 123 can be i-type, p-type or n-type semiconductor.

The transparent conductive layer 18 can spread current and provide good electrical contact with the second semiconductor layer 122, such as ohmic contact. The transparent conductive layer 18 is transparent to the light emitted from the active region 123. For example, the transparent conductive layer 18 has a transmittance of more than 80% to the light emitted from the active region 123. The material of the transparent conductive layer 18 can be a metal or a transparent conductive material. The metal material includes Au, Ni/Au, etc. The transparent conductive material includes graphene, ITO, AZO, GZO, ZnO, IZO or the like.

Then, referring to FIG. 1B, a first contact layer 201, a second contact layer 301, a protective layer 40, a first electrode 20 and a second electrode 30 are formed on the plurality of mesas M and the upper surface 121a of the first semiconductor layer 121. The first contact layer 201 and the second contact layer 301 are formed on the first semiconductor layer 121 and the transparent conductive layer 18 respectively. The materials of the first contact layer 201 and the second contact layer 301 include metals, such as Cr, Ti, W, Au, Al, Rh, In, Sn, Be, Ge, Ni, Pt, Ag or a laminated stack or an alloy of the above materials. In one embodiment, the first contact layer 201 and the second contact layer 301 include the same material stack and have substantially the same thickness. In another embodiment, the transparent conductive layer 18 is not formed, and the second contact layer 301 can be formed directly on the second semiconductor layer 122. The first contact layer 201 and the second contact layer 301 may include the same metal stack or different metal stacks. The protective layer 40 covers the semiconductor stack 12, the transparent conductive layer 18 and the first and second contact layers 201 and 301, and includes an opening 401 exposing the first contact layer 201 and an opening 402 exposing the second contact layer 301. The protective layer 40 can be a multi-layered structure or a single-layered structure, and the material thereof includes insulating materials, such as silicon oxide, silicon nitride, silicon oxynitride, niobium oxide, hafnium oxide, titanium oxide, magnesium fluoride, or aluminum oxide. In one embodiment, the protective layer 40 includes a dense layer with a thickness between 50 Å and 2000 Å. In one embodiment, between 100 Å and 1500 Å. The dense layer can be formed by atomic layer deposition (ALD). In one embodiment, the dense layer formed by ALD can conformably cover the semiconductor stack 12. Due to the characteristic of good step coverage of the dense layer, the dense layer can protect the semiconductor stack 12, such as preventing moisture from entering the semiconductor stack 12. The first electrode 20 and the second electrode 30 are formed on the protective layer 40. The first electrode 20 is filled in the opening 401, contacts the first contact layer 201 and electrical connects with the first semiconductor layer 121. The second electrode 30 is filled in the opening 402, contacts the second contact layer 301 and electrically connects with the second semiconductor layer 122. A portion of the first electrode 20 is further located on the second semiconductor layer 122. The first electrode 20 and the second electrode 30 include metal materials, such as Cr, Ti, W, Au, Al, In, Sn, Ni, Pt, Ag or a laminated stack or an alloy of the above materials. In one embodiment, the first electrode 20 and the second electrode 30 may include the same material stack and have substantially the same thickness.

In another embodiment, the first contact layer 201 is omitted and the opening 401 of the protective layer 40 exposes the first semiconductor layer 121; and/or the second contact layer 301 is omitted and the opening 402 exposes the transparent conductive layer 18.

Next, referring to FIG. 1C, an insulating stack 50 is formed on the semiconductor stack 12. The insulating stack 50 covers the protective layer 40, the first electrode 20 and the second electrode 30. FIGS. 2A and 2B show the detailed structure of the insulating stack 50 in accordance with different embodiments. In one embodiment shown in FIG. 2A, the insulating stack 50 includes a first stack 50A. The first stack 50A includes one or more pairs of insulating layers and one pair of the insulating layers is composed by a first sub-layer 50a and a second sub-layer 50b. The first stack 50A includes insulating material. The first sub-layer 50a has a different material from that of the second sub-layer 50b and has a refractive index higher than that of the second sub-layer 50b. In one embodiment, the first sub-layer 50a has a smaller thickness than the second sub-layer 50b. The first sub-layer 50a and the second sub-layer 50b include insulating material such as silicon oxide, silicon nitride, silicon oxynitride, niobium oxide, hafnium oxide, titanium oxide, magnesium fluoride, or aluminum oxide. By selecting materials with different refractive index and the thicknesses thereof, the insulating stack 50 can reflect light within a specific wavelength range and/or a specific incident angle range, that is, the insulating stack 50 can be a reflective structure. In one embodiment, the insulating stack 50 includes distributed Bragg reflector. For example, the insulating stack 50 has a reflectance of more than 60% of the dominant wavelength and/or the peak wavelength of the light-emitting device 1.

In another embodiment, the insulating stack 50 further includes additional layers other than the first sub-layer 50a and the second sub-layer 50b. For example, the insulating stack 50 further includes a bottom layer (not shown) between the first stack 50A and the semiconductor stack 12. In other words, the bottom layer is formed on the semiconductor stack 12 first, and then the first sub-layers 50a and the second sub-layers 50b are formed on the bottom layer. In one embodiment, the bottom layer includes insulating material which can be the same as one of the first sub-layers 50a and the second sub-layers 50b or different from both of the first sub-layers 50a and the second sub-layers 50b. The thickness of the bottom layer is greater than those of the first sub-layer 50a and the second sub-layer 50b. In one embodiment, the bottom layer can be formed by a process different from that for forming the first sub-layer 50a and the second sub-layer 50b. For example, the bottom layer is formed by CVD, and preferably, formed by plasma enhanced chemical vapor deposition (PECVD). The first sub-layers 50a and the second sub-layers 50b can be formed by sputtering or evaporation. In one embodiment, the bottom layer can protect the light-emitting device or the semiconductor stack, for example, prevent moisture from penetrating the light-emitting device.

In another embodiment, the insulating stack 50 further includes a top layer (not shown) formed on one side of the first stack 50A opposite to the second semiconductor layer 122. In other words, the first sub-layers 50a and the second sub-layers 50b are formed on the semiconductor stack 12 first, and then the top layer is formed. The top layer includes insulating material which can be the same as one of the first sub-layers 50a and the second sub-layers 50b or different from both of the first sub-layers 50a and the second sub-layers 50b. The thickness of the top layer is greater than the thicknesses of the first sub-layer 50a and the second sub-layer 50b. In one embodiment, the top layer can be formed by a process different from that for forming the first sub-layer 50a and the second sub-layer 50b. For example, the top layer is formed by chemical vapor deposition (CVD), and preferably, formed by plasma enhanced chemical vapor deposition (PECVD). The first sub-layers 50a and the second sub-layers 50b can be formed by sputtering or evaporation. In one embodiment, the top layer can improve the robustness of the insulating stack 50. For example, when the insulating stack 50 is subject to an external force, the top layer can prevent the insulating stack 50 from being broken and damaged due to the external force.

In another embodiment shown in FIG. 2B, the insulating stack 50 includes a plurality of stacks. For example, the insulating stack 50 includes the first stack 50A and a second stack 50B. The second stack 50B includes one or more pairs of insulating layers and one pair of insulating layers is composed by a third sub-layer 50c and a fourth sub-layer 50d. The second stack 50B includes insulating material. The third sub-layer 50c has a different material from that of the fourth sub-layer 50d and has a refractive index higher than that of the fourth sub-layer 50d. In one embodiment, the third sub-layer 50c has a smaller thickness than that of the fourth sub-layer 50d. The third sub-layer 50c and the first sub-layer 50a have different thicknesses, and the third sub-layer 50c and the first sub-layer 50a can be the same material or different materials. The fourth sub-layer 50d and the second sub-layer 50b have different thicknesses, and the fourth sub-layer 50d and the second sub-layer 50b can be the same material or different materials. In another embodiment, the insulating stack 50 includes the plurality of stacks, the bottom layer and/or the top layer.

As shown in FIG. 1C, the thickness t1 of the insulating stack 50 is between 0.2-5 μm. In one embodiment, between 0.2-3 μm. In one embodiment, t1 is greater than the thickness of the first electrode 20 and the second electrode 30.

Next, referring to FIG. 1D, a sacrificial layer 60 is formed to cover the insulating stack 50, and then the sacrificial layer 60 is planarized to have a substantially flat top surface 60a. The flat top surface 60a means that the top surface of the sacrificial layer 60 substantially has a constant level relative to the XY plane. Methods for forming the sacrificial layer 60 include spin coating, chemical vapor deposition, physical vapor deposition, etc. The material of the sacrificial layer 60 includes organic materials or inorganic materials. Organic materials include, for example, photoresist, polyimide (PI), BCB, perfluorocyclobutane (PFCB), Su8, epoxy, acrylic resin, or silicon oxyalkane polymers. Inorganic materials include spin-on glass (SOG), borophosphosilicate glass (BPSG), insulating oxide materials such as silicon oxide, silicon nitride, silicon oxynitride, niobium oxide, hafnium oxide, titanium oxide, magnesium fluoride, or aluminum oxide. In one embodiment, the sacrificial layer 60 is formed by spin coating. By controlling the processing parameters of the spin coating, the sacrificial layer 60 substantially has the flat top surface 60a after being formed. In another embodiment, the sacrificial layer 60 is formed by spin coating, chemical vapor deposition or physical vapor deposition, and then a part of the sacrificial layer 60 is removed by grinding, such as chemical-mechanical planarization (CMP), to planarize the sacrificial layer 60, and finally the flat top surface 60a is formed. In another embodiment, after the sacrificial layer 60 is formed by spin coating, the top surface of the sacrificial layer 60 is then mechanically pressed, so that the flat top surface 60a is formed.

Next, referring to FIG. 1E, a part of the sacrificial layer 60 and a part of the insulating stack 50 are removed from the flat top surface 60a downward until a top surface S1 of the first electrode 20 and a top surface S2 of the second electrode 30 are exposed. Specifically, the top surface S1 of the first electrode 20 on the second semiconductor layer 122 is exposed. The method of removing the sacrificial layer 60 and the insulating stack 50 includes etching. In one embodiment, the sacrificial layer 60 and the part of the insulating stack 50 which is removed include the same material. In another embodiment, the removed part of the sacrificial layer 60 and the insulating material stack 50 include different materials, for example, different materials with similar or identical etching rates. For example, the insulating stack 50 includes the top layer as described in the above embodiment, wherein the material of the top layer includes silicon dioxide. The sacrificial layer 60 can be silicon dioxide or spin-on glass. Part of the top layer in the insulating stack 50 and the sacrificial layer 60 are removed during the present step.

As shown in FIG. 1E, after this step is completed, the remaining insulating stack 50 has a top surface S3 located around the top surface S1 of the first electrode 20, the top surface S2 of the second electrode 30, and between S1 and S2. In one embodiment, the top surface S3 is substantially parallel to the XY plane, S1 and/or S2. The top surface S1 of the first electrode 20 and the top surface S3 of the insulating stack 50 have approximate levels. The insulating stack 50 includes a first part located on the upper surface 122a of the second semiconductor layer 122 and between the first electrode 20 and the second electrode 30, a second part located on the upper surface 121a of the first semiconductor layer, and a third part covering first electrode 20. The first part has a thickness t2 and the second part has a thickness t3, where t3 is greater than t2. In one embodiment, t3 is substantially equal to t1. Referring to FIG. 1C and FIG. 1D, t1 is the thickness of the insulating stack 50 before the step of removing parts of the sacrificial layer 60 and the insulating stack 50. In one embodiment, the thickness of the third part of the insulating stack 50 is equal to or less than t1. In one embodiment, the top surfaces S1 and S3 are substantially at the same level. In another embodiment, the level of the top surface S3 is slightly lower than that of the top surface S1 so that parts of a side surface of the first electrode 20 can be exposed, and the difference in level between S1 and S3 is less than 0.5 μm. In one embodiment, the thickness of the second contact layer 301 is much smaller than the first electrode 20 and the second electrode 30, so that the top surface S1 of the first electrode 20 and the top surface S2 the second electrode 30 have similar or substantially equal levels. The difference in level therebetween is less than 0.5 μm. The top surfaces S2 and S3 substantially have the same level or the difference in level between S2 and S3 is less than 0.5 μm. In one embodiment, the top surface S3 is slightly lower than S2 so that parts of a side surface of the second electrode 30 can be exposed. In another embodiment, the second contact layer 301 is not formed, the second electrode 30 is filled in the opening 402 and contacts the transparent conductive layer 18, and the top surface S1 of the first electrode 20 and the top surface S2 of the second electrode 30 substantially have the same level or the difference in level therebetween is less than 0.5 μm. In one embodiment, during the process of removing parts of the sacrificial layer 60 and the insulating stack 50 downwardly from the flat top surface 60a, the top surface of the electrode 20 or 30 may be damaged. Therefore, the top surface S1 shown in FIG. 1E may be slightly lower than the top surface S1 shown in FIG. 1D (also, the top surface S2 shown in FIG. 1E may be slightly lower than the top surface S2 shown in FIG. 1D).

Next, referring to FIG. 1F, an isolation region ISO is formed. The isolation region ISO is used to separate the semiconductor stack 12 on the substrate 10 and define a plurality of light-emitting devices 1 in subsequent processes. As shown in FIG. 1F, the method of forming the isolation region ISO includes removing parts of the first semiconductor stack 121, the protective layer 40, the insulating stack 50 and the sacrificial layer 60 to expose the top surface 10a of the substrate 10. In another embodiment (not shown), the isolation region ISO can be formed by removing the insulating stack 50, the sacrificial layer 60, the protective layer 40 and one part of the first semiconductor stack 121, and the other part of the first semiconductor stack 121 are remained on the top surface 10a, so that the isolation region ISO exposes another upper surface of the first semiconductor stack 121.

Next, referring to FIG. 1G, the first electrode pad 20A, the second electrode pad 30A are formed and the substrate 10 is divided in to a plurality of light-emitting devices 1. In each light-emitting device 1, a first electrode pad 20A and a second electrode pad 30A are formed on the first electrode 20 and the second electrode 30 respectively. The first electrode pad 20A contacts the top surface S1 of the first electrode 20, and the second electrode pad 30A contact the top surface S2 of the second electrode 30. The first electrode pad 20A and the second electrode pad 30A can be further formed on and contacts the top surface S3 of the insulating stack 50. In another embodiment, the first electrode pad 20A and the second electrode pad 30A can be formed and then the isolation region ISO as shown in FIG. 1F is subsequently formed.

The materials of the first electrode pad 20A and the second electrode pad 30A include metal, such as Cr, Ti, W, Au, Al, In, Sn, Ni, Pt, Ag, a laminated stack or an alloy of the above materials. For example, the first electrode pad 20A and the second electrode pad 30A include Al/Pt, Ti/Au, Ti/Pt/Au, Cr/Au, Cr/Pt/Au, Ni/Au, Ni/Pt/Au, Cr/Al/Ti/Pt, Ti/Al/Ti/Pt/Ni/Pt, Cr/Al/Ti/Al/Ni/Pt/Au, Cr/Al/Cr/Ni/Au or Ag/NiTi/TiW/Pt. In one embodiment, the light-emitting device 1 is bonded to a circuit carrier board (not shown) via the first electrode pad 20A and the second electrode pad 30A in a flip-chip bonding. The light-emitting device 1 is electrically connected to external electronic component or power source through the circuits on the circuit carrier board. The first electrode pad 20A and the second electrode pad 30A provide a current path for an external power source to supply power to the first semiconductor layer 121 and the second semiconductor layer 122. The size and shape of the first electrode pad 20A can be the same as or different from the first electrode 20 (or the second electrode 30). In an embodiment that the sizes of the electrode pads 20A and 30A are larger than the sizes of the first electrode 20 and the second electrode 30, a larger bonding area can be formed between the light-emitting device 1 and the circuit carrier board, thereby improving the bonding yield.

In another embodiment (not shown), after forming the electrode pads 20A and 30A and the isolation region ISO, the substrate 10 is not divided. Top sides of the electrode pads 20A and 30A are bonded to a first temporary carrier, and then the substrate 10 is separated and removed from the semiconductor stack 12 to expose a lower surface 121b of the semiconductor stack 12. In another embodiment (not shown), after the substrate 10 is removed as described above, the exposed lower surface 121b of the semiconductor stack 12 is bonded to a second temporary carrier, and then the first temporary carrier is removed. The first temporary carrier is separated from the electrode pads 20A and 30A to expose the electrode pads 20A and 30A. Methods for removing the substrate 10, the first and second temporary carriers include but are not limited to etching or laser lift-off. Methods for bonding the electrode pads with the temporary carrier or bonding the semiconductor stack 12 with the temporary carrier include but are not limited to glue bonding.

FIG. 1G and FIG. 1H show the light-emitting device 1 manufactured by the method in accordance with the above embodiment of the present application. FIG. 1H shows the top view of the light-emitting device 1. The light-emitting device 1 includes the semiconductor stack 12, the first contact layer 201 formed on and electrically connected to the first semiconductor layer 121, the second contact layer 301 formed on and electrically connected to the second semiconductor layer 122, the protective layer 40 covering the semiconductor stack 12 and the contact layers 201 and 301, including the opening 401 exposing the first contact layer 201 and the opening 402 exposing the second contact layer 301, the first electrode 20 and the second electrode 20 formed on the protective layer 40, respectively filled in the openings 401 and opening 402 to electrically connect the first contact layer 201 and the second contact layer 301, wherein the first electrode 20 includes the first top surface S1 and the second electrode 30 includes the second top surface S2. The insulating stack 50 covers the semiconductor stack 12 and includes the third top surface S3 that is substantially parallel to the first top surface S1 and the second top surface S2. In a top view, the third top surface S3 is located around the first top surface S1 and the second top surface S2. The first electrode pad 20A is located on the insulating stack 50 and the first electrode 20, and is connected with the first top surface S1. The second electrode pad 30A is located on the insulating stack 50 and the second electrode 20, and is connected to the second top surface S2. The first top surface S1 and the third top surface S3 have a similar level or substantially the same level. The difference in level between the two is less than 0.5 μm. In one embodiment, the first electrode pad 20A and the second electrode pad 30A can further contact the third top surface S3. In one embodiment, the light-emitting device 1 does not include the contact layers 201 and 301, and the top surfaces S1, S2 and S3 have similar levels or are substantially the same level, and the difference in level between any two of S1, S2 and S3 is less than 0.5 μm. The insulating stack 50 includes the first part located on the upper surface 122a of the second semiconductor layer 122 and between the electrodes 20 and 30, and the second part located on the upper surface 121a of the first semiconductor layer 121. The first part has the thickness t2 and the second part has the thickness t3. In one embodiment, t3 is greater than t2.

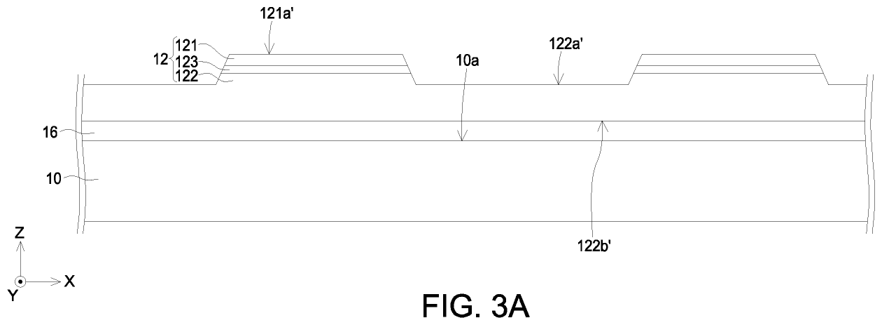

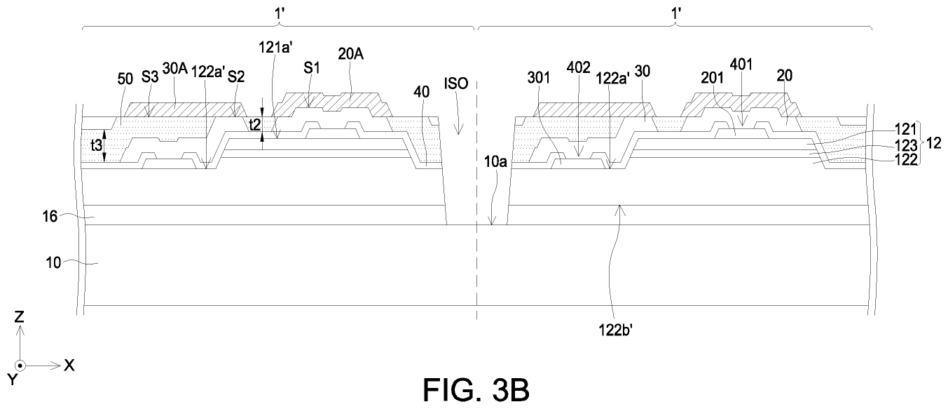

In other embodiments of the present application, the semiconductor stack 12 can be formed on the substrate 10 by different methods. For example, as shown in FIG. 3A, after the semiconductor stack 12 is formed on a growth substrate (not shown) by epitaxial growth, the semiconductor stack 12 is attached to the substrate 10 from a surface 122b′ of the second semiconductor layer 122 by a bonding layer 16, and then the growth substrate is removed to expose the surface 121a′ of the first semiconductor layer 121. Parts of the first semiconductor layer 121 and the active region 123 are removed to expose the upper surface 122a′ of the second semiconductor layer 122. Next, referring to FIG. 3B, similar to the manufacturing method of the light-emitting device 1 in accordance with previous embodiment, the contact layers 201 and 301, the electrodes 20 and 30, the protective layer 40, the insulating stack 50, the sacrificial layer 60, and the electrode pads 20A and 30A, the isolation region ISO are formed. Finally, the light-emitting device 1′ is completed as shown in FIG. 3B. The structure of the light-emitting device 1′ is similar to that of the light-emitting device 1. The difference is that the light-emitting device 1′ includes the bonding layer 16 between the semiconductor stack 12 and the substrate 10. The bonding layer 16 can be further removed during forming the isolation region ISO, thereby exposing the top surface 10a. In addition, the stacking order of the first semiconductor layer 121, the active region 123 and the second semiconductor layer 122 in the light-emitting device 1′ is opposite to that of the light-emitting device 1, and the contact layers 201 and 301, the electrodes 20 and 30 and the electrode pads 20A and 30A which are electrically connected to the semiconductor stack 12 are also opposite to those of the light-emitting device 1. In another embodiment (not shown), after forming the semiconductor stack 12 on the growth substrate by epitaxial growth, the semiconductor stack 12 is bonded to the first temporary carrier in a first bonding process, and the growth substrate is removed. Next, the surface of the semiconductor stack 12 exposed by removing the growth substrate is bonded to the substrate 10 in a second bonding process, and then the first temporary carrier is removed. Next, similar to the manufacturing method of the light-emitting device 1 in previous embodiment, the contact layers 201 and 301, the electrodes 20 and 30, the protective layer 40, the insulating stack 50, the sacrificial layer 60, the electrode pads 20A and 30A and the isolation region ISO are formed. In one embodiment, the bonding process can be performed using the aforementioned bonding layer 16. In this manner, the light-emitting device 1′ includes the substrate 10, the bonding layer 16, the first semiconductor layer 121, the active region 123 and the second semiconductor layer 122 in this order.

The bonding layer 16 is transparent to the light emitted by the semiconductor stack 12, and its material can be insulating and/or conductive material. The insulating material includes organic materials and inorganic materials. The organic material includes but is not limited to polyimide (PI), benzocyclobutene (BCB), perfluorocyclobutane (PFCB), Su8, epoxy, acrylic resin, cyclic olefin polymer (COC), polymethyl methacrylate (PMMA), polyethylene terephthalate (PET), polycarbonate (PC), polyetherimide (Polyetherimide) and fluorocarbon polymer. The inorganic material includes, for example, glass, Al₂O₃, SiOₓ, TiO₂, SiNₓ, MgO or spin-on glass (SOG). The conductive material includes but is not limited to indium tin oxide, indium oxide, tin oxide, cadmium tin oxide, antimony tin oxide, aluminum zinc oxide, zinc tin oxide, zinc oxide, indium zinc oxide, tantalum oxide, diamond-like carbon, or gallium zinc oxide.

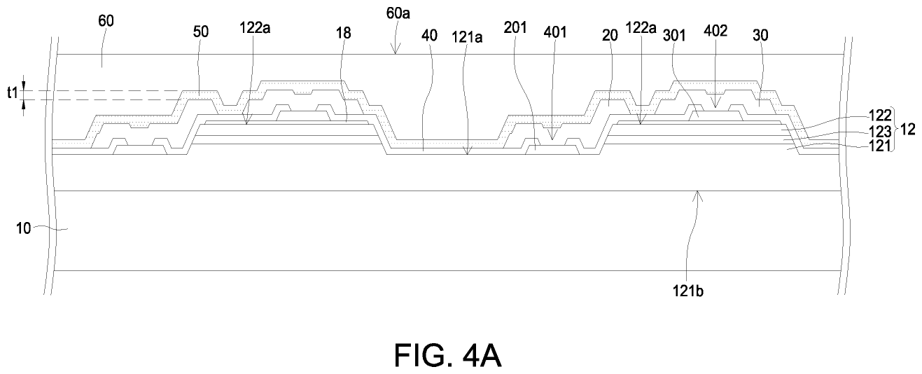

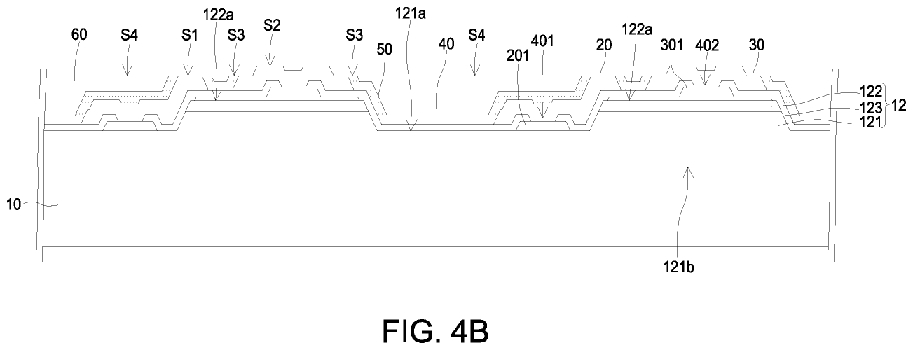

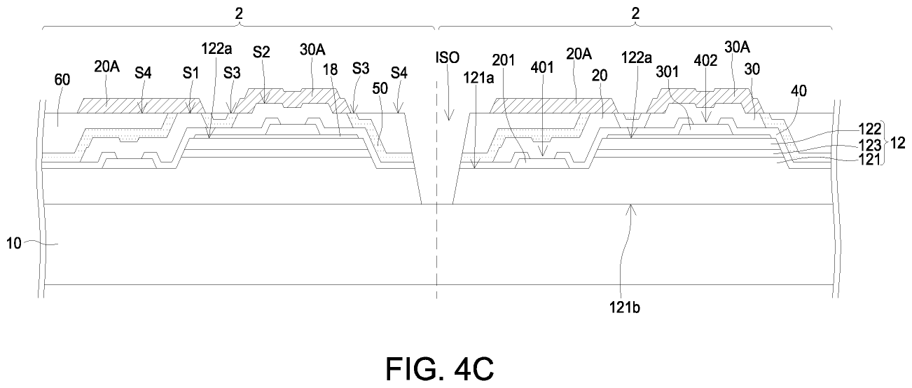

FIGS. 4A to 4C show a manufacturing method of a light-emitting device 2 in accordance with another embodiment of the present application. If the details of each elements of the light-emitting device in accordance with the present embodiment and other embodiments of the present application, such as material and thickness, are not specifically described in this embodiment and have the same name and same label as those of the light-emitting device 1, the details can be referred to the description of the light-emitting device 1, and will not be repeated. Referring to FIG. 4A, like the aforementioned embodiment, the semiconductor stack 12, the transparent conductive layer 18, the contact layers 201 and 301, the protective layer 40, the electrodes 20 and 30, the insulating stack 50 and the sacrificial layer 60 with the flat top surface 60a are formed. Being different from FIG. 1D, the thickness t1 of the insulating stack 50 of the light-emitting device 2 shown in FIG. 4A is smaller than the thickness of the electrodes 20 and 30 and the insulating stack 50 is conformably formed on the underlying structure. Next, referring to FIG. 4B, like the embodiment shown in FIG. 1E, part of the sacrificial layer 60 and part of the insulating stack 50 are removed from the flat top surface 60a, so that the top surface S1 of the first electrode 20 and the top surface S2 of the second electrode 30 are exposed. The difference between FIG. 4B and FIG. 1E is that the remaining sacrificial layer 60 covers the first electrode 20 and the insulating stack 50 and includes a fourth top surface S4 located around the first top surface S1, the second top surface S2, and the third top surface S3 in FIG. 4B. The fourth top surface S4 is substantially parallel to the XY plane. In on embodiment, the first top surface S1 and the fourth top surface S4 have similar levels. In one embodiment, the top surfaces S1 and S4 are substantially at the same level. In another embodiment, the level of the fourth top surface S4 is slightly lower than that of the first top surface S1, and the difference in level between the two is less than 0.5 μm. In another embodiment, the fourth top surface S4 and the third top surface S3 have a similar or substantially equal level. In another embodiment, the difference in level between any two of the top surfaces S1, S3 and S4 is less than 0.5 μm.

Next, referring to FIG. 4C, like the aforementioned embodiment shown in FIG. 1G, the first electrode pad 20A, the second electrode pad 30A and the isolation region ISO are formed. The substrate 10 can be divided to form a plurality of individual light-emitting devices 2. In addition, in another embodiments, like the manufacturing method of the aforementioned light-emitting device 1, the substrate 10 can be bonded to the first temporary carrier or the first and second temporary carriers without being divided.

As shown in FIG. 4C, in the light-emitting device 2 formed by the manufacturing method in accordance with one embodiment of the present application, the sacrificial layer 60 is left during the manufacturing process and forms a covering layer. In the present application, the sacrificial layer and the covering layer have the same label. The difference between the light-emitting device 2 and the light-emitting device 1 is that the covering layer 60 includes a fourth top surface S4 located around the first top surface S1, the second surface S2 and the third top surface S3, and in one embodiment, the fourth top surface S4 is substantially parallel with S1 to S2. In one embodiment, the fourth top surface S4 and the first top surface S1 have similar or substantially equal levels. In another embodiment, the fourth top surface S4 and the third top surface S3 have a similar or substantially equal level. In another embodiment, the difference in level between S4 and S3 and/or the difference in level between S4 and S1 is less than 0.5 μm. The first electrode pad 20A and the second electrode pad 30A are located on the covering layer 60, wherein the first electrode pad 20A and/or the second electrode pad 30A can further contact the fourth top surface S4.

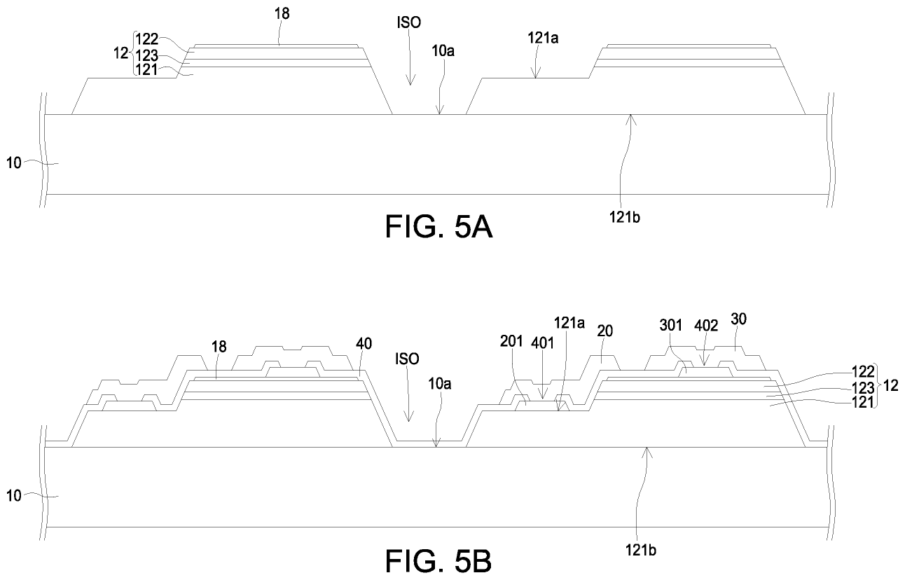

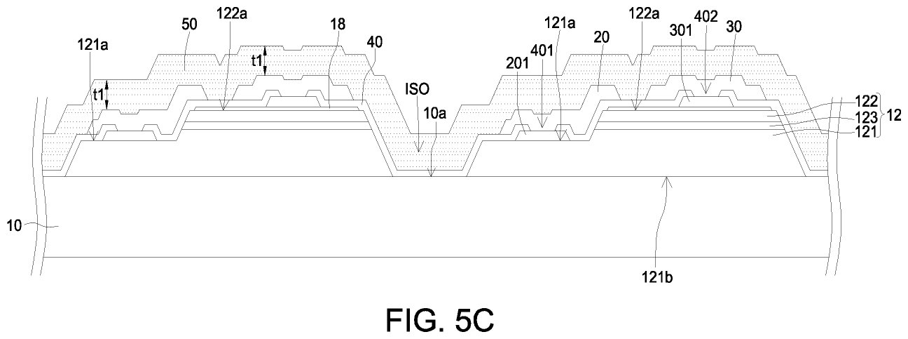

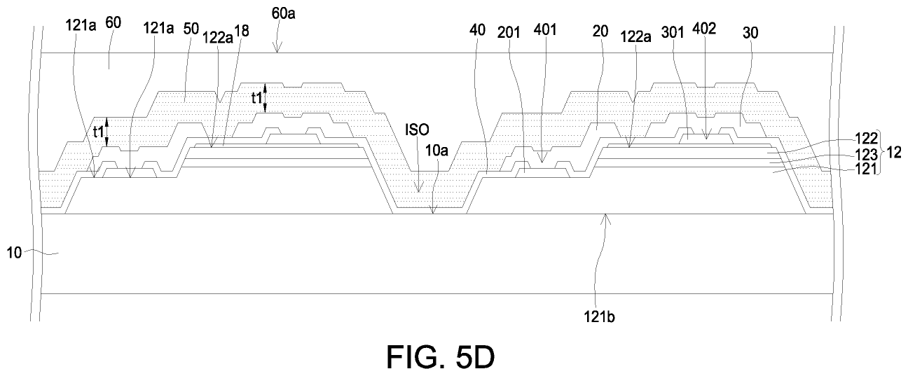

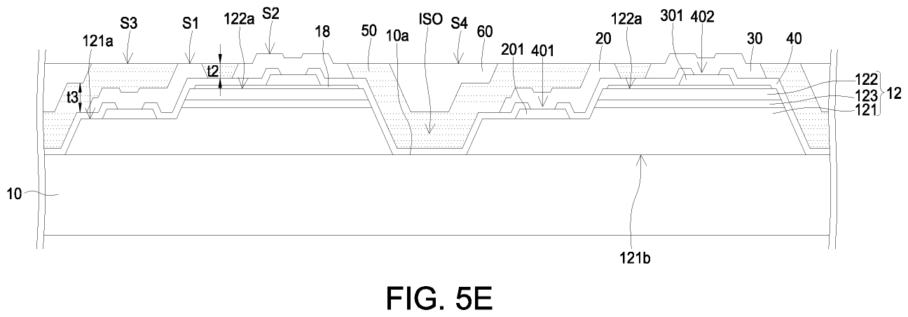

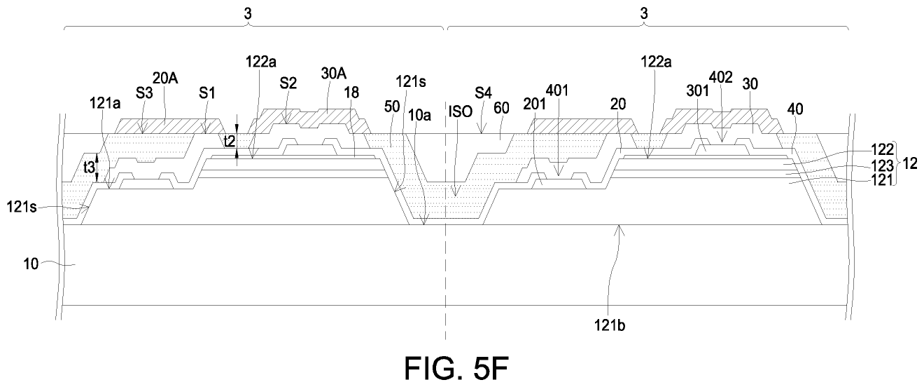

FIGS. 5A to 5C show a manufacturing method of a light-emitting device 3 in accordance with another embodiment of the present application. Referring to FIG. 5A, the semiconductor stack 12 and the transparent conductive layer 18 are formed on the top surface 10a of the substrate 10, and the isolation region ISO is formed to separate the semiconductor stack 12 on the substrate 10, and in subsequent processes, a plurality of light-emitting devices 3 is defined. Next, referring to FIG. 5B, the contact layers 201 and 301, the protective layer 40, and the electrodes 20 and 30 are formed. Like the aforementioned embodiments, the isolation region ISO can expose the top surface 10a of the substrate 10 or a part of the first semiconductor layer 121 can be remained in the isolation region ISO. The difference between the present embodiment and the embodiment shown in FIG. 1B is that, the protective layer 40 in the present embodiment further covers the isolation region ISO, that is, the protective layer 40 extends to cover the sidewalls of the first semiconductor layer 121 and the top surface 10a of the substrate 10. In another embodiment, the protective layer 40 extends to cover the sidewalls of the first semiconductor layer 121 but not cover the top surface 10a of the substrate 10. Next, referring to FIG. 5C, the insulating stack 50 is formed, wherein the insulating stack 50 covers the protective layer 40 in the isolation region ISO, thereby covering the sidewalls of the first semiconductor layer 121 as well. Next, referring to FIG. 5D, the sacrificial layer 60 is formed and further filled in the isolation region ISO. Next, as shown in FIGS. 5E and 5F, similar to the manufacturing method of the light-emitting device 1, part of the sacrificial layer 60 and part of the insulating stack 50 are removed from the flat top surface 60a to expose the first top surface S1 of the first electrode 20 and the second top surface S2 of the second electrode 30 are exposed, and the third top surface S3 of the insulating stack 50 and the fourth top surface S4 of the sacrificial layer 60 are formed. Finally, as shown in FIG. 5F, the first electrode pad 20A and the second electrode pad 30A are formed. In one embodiment, the substrate 10 can be divided along the isolation ISO to form a plurality of individual light-emitting device 3. In another embodiments, like the manufacturing method of the light-emitting device 1, the substrate 10 can be bonded to the first temporary carrier or the first and second temporary carriers without being divided.

As shown in FIG. 5F, in the light-emitting device 3 manufactured in accordance with the embodiment of the present application, the sacrificial layer 60 is remained during the manufacturing process and forms the covering layer. The difference between the light-emitting device 3 and the light-emitting device 1 is that the protective layer 40 and the insulating stack 50 cover the sidewalls of the first semiconductor layer 121, specifically, cover the sidewalls 121s below the upper surface 121a of the first semiconductor layer. In this way, the reflection of light on the sidewalls 121s can be increased, thereby improving the brightness. The covering layer 60 covers the sidewalls of the insulating stack 50, and the fourth to surface S4 of the covering layer 60 has substantially the same level as the third top surface S3. In another embodiment, the difference in level between the upper surfaces S4 and S3 and/or between the upper surfaces S4 and S1 is less than 0.5 μm. In one embodiment, the covering layer 60 is located around the light-emitting device 3 and can be used to protect the light-emitting device 3. In another embodiment (not shown), like the light-emitting device 2 shown in FIG. 4C, the thickness t1 of the insulating stack of the light-emitting device 3 can be smaller than the thickness of the electrodes 20 and 30, and the first electrode pad 20A and/or the second electrode pad 30A can be formed on the fourth top surface S4 of the covering layer 60.

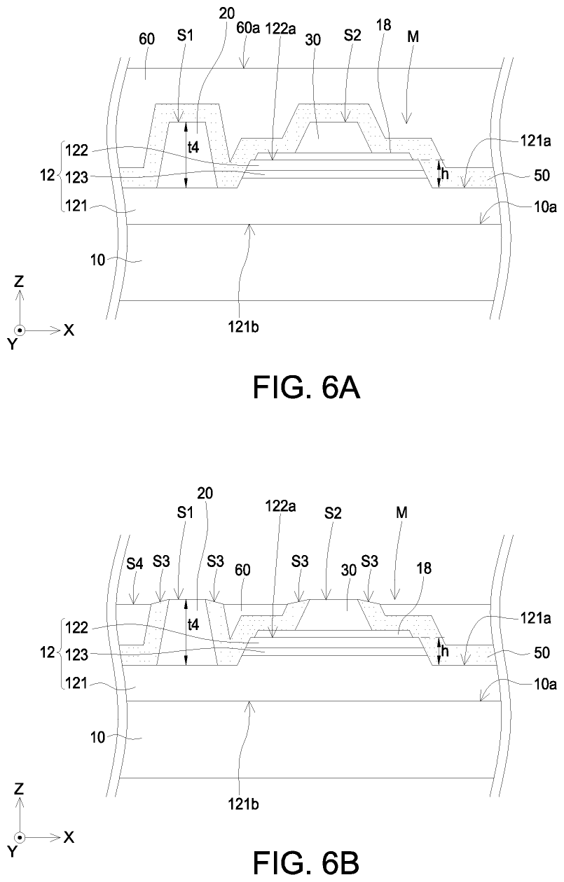

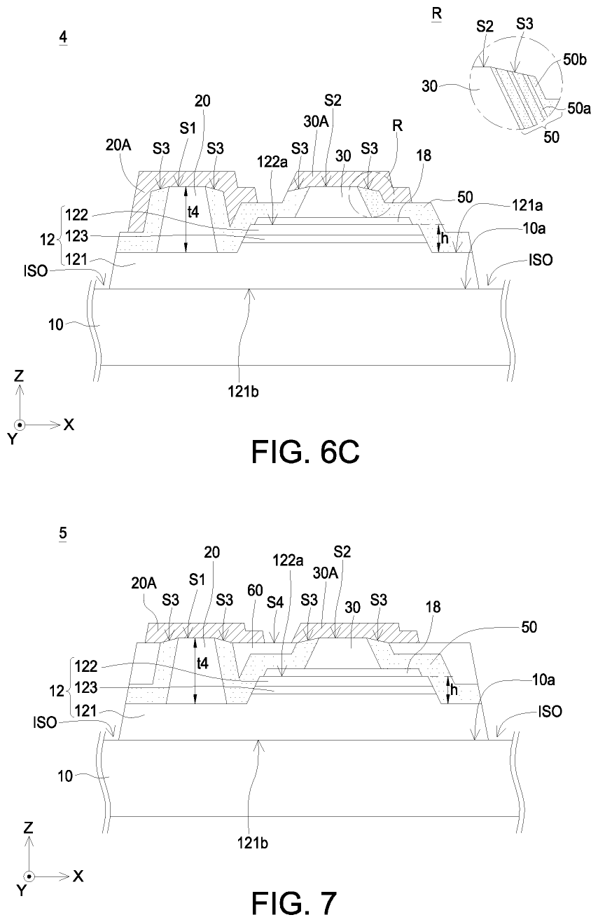

FIGS. 6A to 6C show a manufacturing method for a light-emitting device 4 in accordance with another embodiment of the present application. Referring to FIG. 6A, the semiconductor stack 12, the mesa M and the transparent conductive layer 18 are formed on the top surface 10a of the substrate 10. The difference from the aforementioned light-emitting device 1 is that the first electrode 20, the second electrode 30, the insulating stack 50 and the sacrificial layer 60 are formed without forming the first contact layer 201, the second contact layer 301 and the protective layer 40. In another embodiment, the contact layer (not shown) can be formed in the same step with the electrode. For example, the first contact layer and the first electrode are formed with the same photomask in a photolithography process, or the second contact layer and the second electrode are formed with the same photomask in a photolithography process. The first electrode 20 and the second electrode 30 include different metal stacks and different thicknesses. In one embodiment, the thickness t4 of the first electrode 20 is between 0.8-4 μm. In one embodiment, the thickness t4 of the first electrode 20 is greater than the sum of the height h of the mesa M and the thickness of the transparent conductive layer 18. In another embodiment, the transparent conductive layer 18 is not formed, and the thickness t4 of the first electrode 20 is greater than the height h. In one embodiment, the thickness t4 of the first electrode 20 is similar to or substantially equal to the sum of the height h of the mesa M, the thickness of the transparent conductive layer 18 and the thickness of the second electrode 30. In one embodiment, the top surface S1 of the first electrode 20 and the top surface S2 of the second electrode 30 have similar or substantially the same level. For example, the difference in level between S1 and S2 is less than 0.5 μm. Next, referring to FIG. 6B, a part of the sacrificial layer 60 and part of the insulating material stack 50 are removed from the flat top surface 60a of the sacrificial layer 60, so that the top surface S1 of the first electrode 20 and the top surface S2 of the second electrode 30 are exposed. Nevertheless, this embodiment is not limited thereto. Part of the side surface of the first electrode 20 close to the top surface S1 and/or part of the side surface of the second electrode 30 close to the top surface S2 can also be exposed. The method of forming the flat top surface 60a of the sacrificial layer 60 and the method of removing parts of the sacrificial layer 60 and the insulating stack 50 can be referred to the previous embodiments and will not be repeated here.

After completing the step, the remaining insulating stack 50 has the top surface S3 and the remaining sacrificial layer 60 has the top surface S4. In a top view, S3 separately surrounds S1 and S2, and the level of S3 can be equal to or lower than those of S1 and S2. The level of S4 can be equal to or lower than that of S3. In one embodiment, the method for removing part of the sacrificial layer 60 and part of the insulating stack 50 includes etching. The sacrificial layer 60 and the insulating stack 50 include different materials. An etching rate of the sacrificial layer 60 is greater than that of the insulating stack 50. The top surface S3 can be inclined relative to the XY plane. For example, the part of S3 which is closest to S1 and S2 has the highest height, and the part of S3 which is farther away from S1 and S2 has a lower height. The level of the highest point of the top surface S3 may be equal to or lower than the levels of the top surfaces S1 and S2. In one embodiment, the difference in level between the highest point of the top surface S3 and the top surface S1 and/or the top surface S2 is less than 1 μm. In another embodiment, materials with the same or similar etching rate can be selected as the sacrificial layer 60 and the insulating stack 50, and the top surface S3 can be substantially parallel to the XY plane.

Next, referring to FIG. 6C, the sacrificial layer 60 can be removed, and the first electrode pad 20A and the second electrode pad 30A are formed on the first electrode 20 and the second electrode 30 respectively, and the isolation region ISO is formed. The first electrode pad 20A and the second electrode pad 30A respectively contact the top surface S1 and the top surface S2, and may further cover the top surface S3 of the insulating stack 50. In one embodiment, the insulating stack 50 is formed by alternately stacking a plurality of the first sub-layers 50a and the second sub-layers 50b. The cross-sections of the first sub-layers 50a and the second sub-layers 50b constitute the top surface S3, as shown in an enlarged view of the local area R in FIG. 6C.

In other embodiments (not shown), the manufacturing method of the light-emitting device 4 can include or exclude the process of forming the sacrificial layer 60. After the insulating stack 50 is formed, a grinding process such as CMP can be applied on an outer side of the insulating stack 50. For example, the insulating stack 50 is grinded along the negative Z-direction until the top surface S1 of the first electrode 20 and the top surface S2 of the second electrode 30 are exposed. In this way, the top surface S3 of the insulating stack 50 can be substantially parallel to the XY plane, and the top surfaces S1, S2 and S3 substantially have the same level or the difference in level between any two of them is less than 0.5 μm.

FIG. 7 shows a cross-sectional view of a light-emitting device 5 in according with another embodiment of the present application. The light-emitting device 5 is similar to the light-emitting device 4 shown in FIG. 6C. The difference is that in the manufacturing method of the light-emitting device 5, the sacrificial layer 60 is not removed and used as the covering layer 60 in the completed device. The first electrode pad 20A and the second electrode pad 30A can be formed on the covering layer 60. In one embodiment, the first electrode pad 20A and/or the second electrode pad 30A may contact the top surface S4 of the covering layer 60.

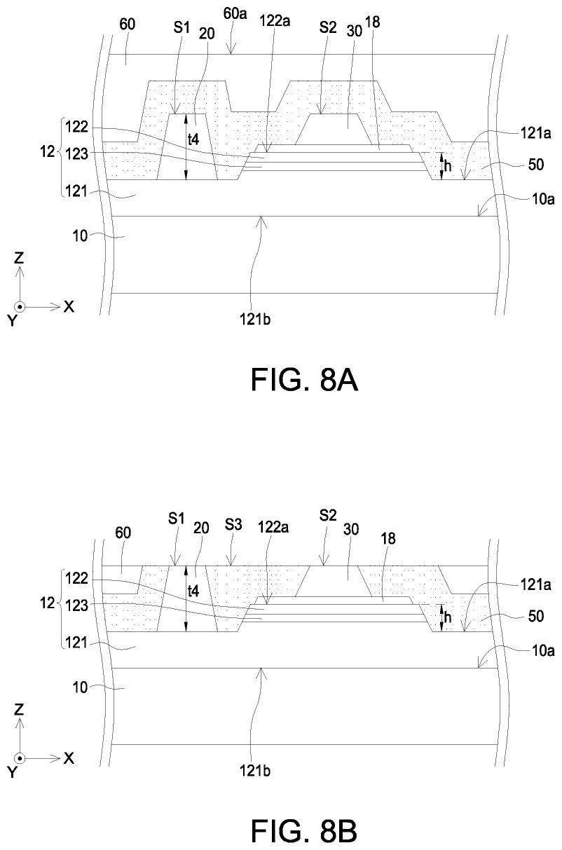

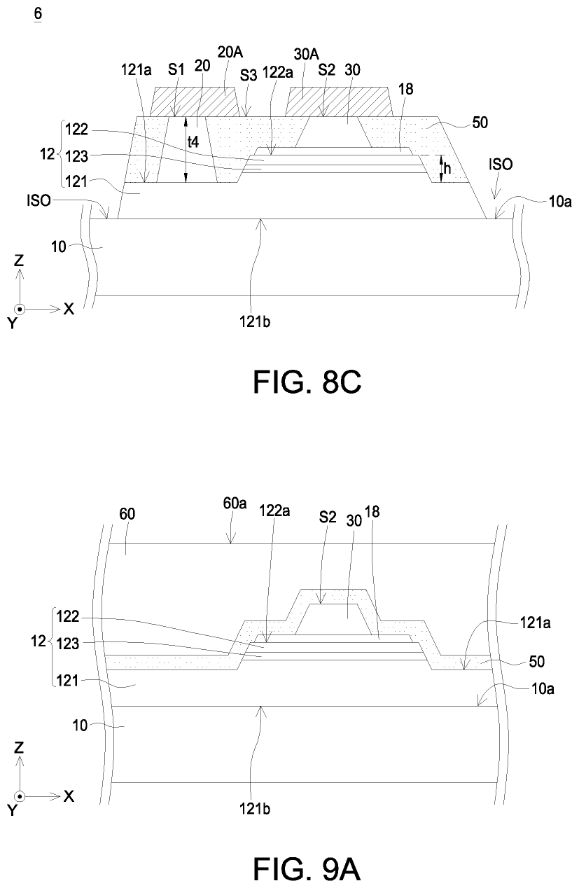

FIGS. 8A to 8C show a manufacturing method of a light-emitting device 6 according to another embodiment of the present application. The manufacturing method of the light-emitting device 6 is similar to that of the light-emitting device 4, the difference is that in the light-emitting device 6, the thickness of the insulating stack 50 is greater than the thickness of the second electrode 30. The thickness of the sacrificial layer 60 can be greater than, equal to, or less than the thickness of the insulating stack 50. The insulating stack 50 with a thicker initial thickness can make an overall level difference on the final top surface of the insulating stack 50 smaller. Referring to FIG. 8B, after removing part of the sacrificial layer 60 and part of the insulating stack 50, most of the sacrificial layer 60 above the insulating stack 50 has been removed. Compared with the insulating stack 50 shown in FIG. 6B, the insulating stack 50 shown in FIG. 8B has a larger area of continuous flat surface of S3. In one embodiment, the top surface S3 may be substantially parallel to the XY plane. Next, as shown in FIG. 8C, the first electrode pad 20A and the second electrode pad 30A are formed on the top surface S3. In this way, the overall difference in level between the first electrode pad 20A and the second electrode pad 30A can be reduced.

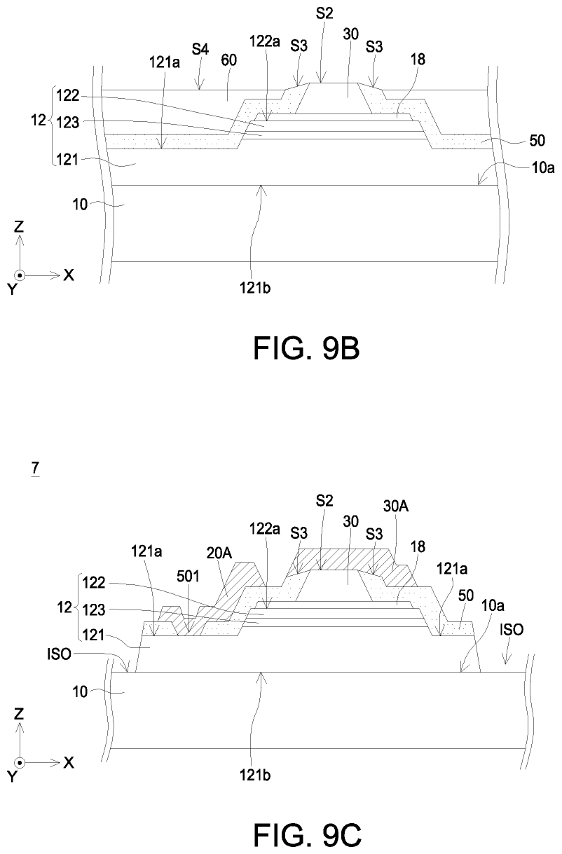

FIGS. 9A to 9C show a manufacturing method of a light-emitting device 7 in accordance with another embodiment of the present application. The manufacturing method of the light-emitting device 7 is similar to that of the light-emitting device 4. The difference is that the manufacturing methods disclosed in the present application can be implemented without the step of forming the first electrode 20. Referring to FIG. 9A, after forming the second electrode 30, the insulating stack 50 and the sacrificial layer 60 are formed. Next, referring to FIG. 9B, part of the sacrificial layer 60 and part of the insulating stack 50 are removed from the flat top surface 60a of the sacrificial layer 60, so that the top surface S2 of the second electrode 30 is exposed and the top surface S3 of the insulating stack 50 is formed. Next, referring to FIG. 9C, after removing the sacrificial layer 60, an opening 501 is formed and exposes the upper surface 121a of the first semiconductor layer 121. Finally, the first electrode pad 20A, the second electrode pad 30A and the isolation region ISO are formed, and the first electrode pad 20A is electrically connected to the first semiconductor layer 121 through the opening 501.

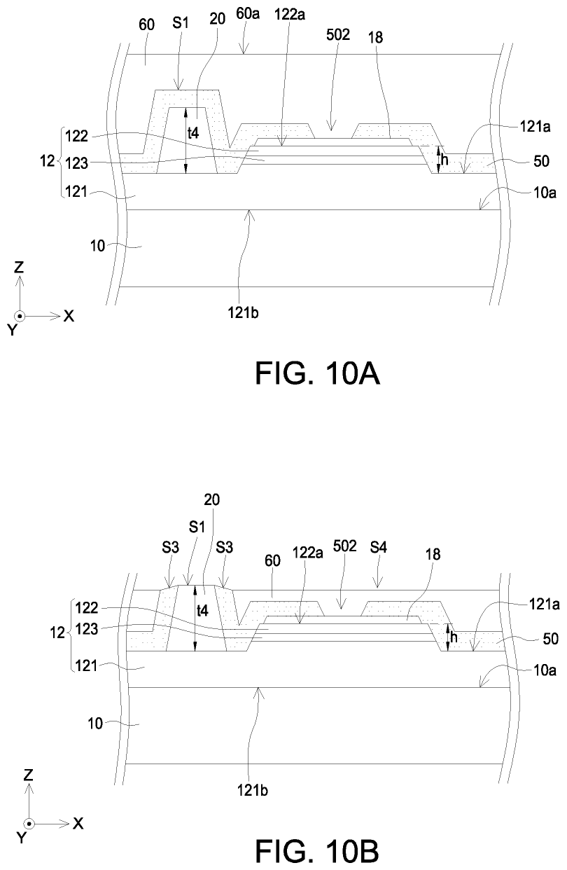

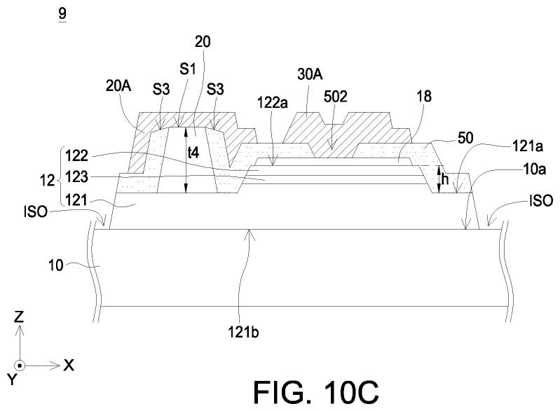

FIGS. 10A to 10C show a manufacturing method of a light-emitting device 9 in accordance with another embodiment of the present application. The manufacturing method of the light-emitting device 9 is similar to that of the light-emitting device 4. The difference is that the manufacturing method of light-emitting device 9 can be implemented without the step of forming the second electrode 30. Referring to FIG. 10A, after forming the first electrode 20, the insulating stack 50 is formed, and an opening 502 is formed in the insulating stack 50. The opening 502 exposes the upper surface 122a of the second semiconductor layer 122 or the transparent conductive layer 18. Next, the sacrificial layer 60 is formed on the insulating stack 50. In one embodiment, the sacrificial layer 60 can be filled in the opening 502. Next, referring to FIG. 10B, part of the sacrificial layer 60 and part of the insulating stack 50 are removed from the flat top surface 60a of the sacrificial layer 60, so that the top surface S1 of the first electrode 20 is exposed and the top surface S3 of the insulating stack 50 is formed. Next, referring to FIG. 10C, after removing the sacrificial layer 60, the first electrode pad 20A, the second electrode pad 30A and the isolation region ISO are formed. The second electrode pad 30A is electrically connected to the second semiconductor layer 122 through the opening 502.

In another embodiments, in the manufacturing method of the light-emitting device in accordance with any embodiment of the present application, the isolation region ISO can be formed before forming the insulating stack 50, as shown in FIGS. 5A and 5B.

In another embodiments, the semiconductor stack 12 of the light-emitting device in accordance with any embodiment of the present application can be bonded to the substrate 10 using the bonding layer 16 as shown in FIG. 3A. The manufacturing process can refer to the aforementioned manufacturing method of the light-emitting device 1. The details will not be described again.

In another embodiments, in the manufacturing method of the light-emitting device in accordance with any embodiment of the present application, like the manufacturing method of the aforementioned light-emitting device 1, the substrate 10 can be bonded to the first temporary carrier or the first and second temporary carriers without being divided.

In a conventional art, in order to electrically connect the electrode pads located on the insulating stack to the semiconductor stack under the insulating stack, openings are formed in the insulating stack and are filled with the electrode pads. In general, the more pairs of insulating layers the insulating stack has, the higher the reflectivity can be achieved. However, as the number of insulating pairs increases, the total thickness of the insulating stack may also increase and raise the difficulty of forming the openings in the insulating stack. When the size of the light-emitting device is reduced and the sizes of the electrode pad and the opening of the insulating stack also become smaller, the required alignment accuracy in the manufacturing process is higher. In addition, when the electrode pad is filled into the openings of the insulating stack, the top surface of the electrode pad also has a level difference due to the thickness of the insulating stack, which can reduce the yield of bonding the electrode pads of the light-emitting device to the circuit carrier board. In the light-emitting devices formed by the manufacturing methods in accordance with the embodiments of the present application, the insulating stack 50 can be used to enhance the brightness of the light-emitting device and solve the above problems. The top surface S3 of the insulating stack 50 has a similar level or substantially the same level as the top surface S1 of the first electrode and the top surface S2 of the second electrode. The level difference between any two of them is less than 0.5 μm. Therefore, the first electrode pad 20A and the second electrode pad 30A can be formed on a flat surface. In addition, the electrode pads 20A and 30A are not affected by the thickness of the insulating stack 50 and the difference in level between the upper surface 121a of the first semiconductor layer 121 and the upper surface 122a of the second semiconductor layer 122, thereby improving the yields of bonding the light-emitting devices to the circuit carrier board or other circuit. Furthermore, compared with the conventional art mentioned above, the manufacturing method of the light-emitting device in accordance with the embodiments of the present application can avoid or reduce the use of photolithography for defining the opening of the insulating stack in the manufacturing process, and avoid the problem of alignment deviation between the opening of the insulating stack and the electrode pad during the manufacturing process.

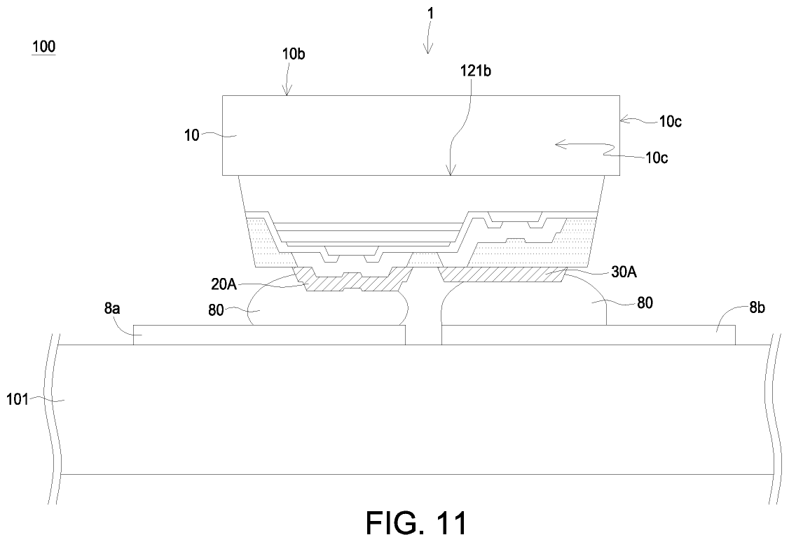

FIG. 11 shows a light-emitting module 100 in accordance with an embodiment of the present application. The light-emitting module 100 includes a carrier 101 which is provided with circuit bonding pads 8a and 8b and used as a circuit carrier board. The first electrode pad 20A and the second electrode pad 30A of the light-emitting device 1 are connected to the circuit bonding pads 8a and 8b through a conductive bonding element 80 by flip-chip bonding. In one embodiment, the bonding method includes but not limited to eutectic bonding, solder bonding or glue bonding, and the conductive bonding element 80 can be, for example, soldering metal, eutectic metal or conductive glue. In this way, most light emitted from the semiconductor stack 12 is extracted through the backside surface 10b and the sidewalls 10c of the substrate 10. In another embodiment, the light-emitting device in accordance with any embodiment of the present application does not have the substrate 10, and the light emitted by the light-emitting device 1 is extracted through the lower surface 121b of the semiconductor stack 12. In one embodiment, the light-emitting module 100 may further include an encapsulant (not shown) on the carrier 101 to cover the light-emitting device 1. The encapsulant includes silicone, epoxy, acrylic or a combination thereof, and the like. In one embodiment, the light-emitting device 1 further includes a reflective structure (not shown) disposed on the backside surface 10b of the substrate 10 for reflecting the light emitted from the semiconductor stack 12, so that most light can be extracted through the sidewalls 10c of the substrate 10. The details of the reflective structure can be referred to the insulating stack 50 described in the above embodiments.

In one embodiment, the light-emitting module 100 can be used as a display module, and a plurality of light-emitting devices 1 is disposed on the carrier 101. The carrier 101 is provided with a circuit (not shown) which includes active electronic components, such as transistors, and is electrically connected to the circuit bonding pads 8a and 8b for driving the light-emitting devices 1. Each of the light-emitting devices 1 can be used as a sub-pixel. Wavelength conversion elements can be formed on the light-emitting devices so that the sub-pixels emit light of different colors, and adjacent sub-pixels form a pixel unit. The wavelength conversion element includes quantum dot, phosphor, color filter, etc. In another embodiment, each light-emitting device 1 includes the semiconductor stack 12 with different materials, so that each light-emitting device 1 emits light with different colors.

The light-emitting devices in accordance with any embodiment of the present application can also be applied to the light-emitting module 100 shown in FIG. 11. The light-emitting device 1 shown in FIG. 11 can be replaced with the light-emitting device in each embodiment, and the first electrode pad 20A and the second electrode pad 30A of the light-emitting device in each embodiment are respectively bonded to the circuit bonding pads 8a and 8b through the conductive bonding element 80 to form the light-emitting module 100 and form the display module. In one embodiment, the light-emitting module 100 includes a plurality of light-emitting devices, wherein the plurality of light-emitting devices includes light-emitting devices in accordance with different embodiments of the present application, and the light-emitting devices in different embodiments emits light with different colors. For example, the light-emitting module 100 includes the light-emitting device 1 and the light-emitting device 1′, wherein the light-emitting device 1 emits blue light or green light, and the light-emitting device 1′ emits red light.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A manufacturing method for a light-emitting device, comprising:
forming a semiconductor stack;
forming an electrode on the semiconductor stack, wherein the electrode comprises a first top surface and a side surface;
forming an insulating stack on the semiconductor stack and the electrode, wherein the insulating stack comprises a plurality of first sub-layers with a first refractive index and a plurality of second sub-layers with a second refractive index alternately stacked;
removing a portion of the insulating stack to expose the first top surface, leaving another portion of the insulating stack having a second top surface surrounding the first top surface, and a level of the second top surface is lower than or equal to that of the first upper surface; and
forming an electrode pad on the insulating stack, wherein the electrode pad contacts the first top surface.

2. The manufacturing method according to claim 1, further comprising:
forming a sacrificial layer on the insulating stack; and
a portion of the sacrificial layer and the portion of the insulating stack are removed to expose the first top surface.

3. The manufacturing method according to claim 2, wherein:
after removing the portion of the sacrificial layer and the portion of the insulating stack, a remaining portion of the sacrificial layer has a third top surface, and a level of the third top surface is lower than or equal to that of the second top surface.

4. The manufacturing method according to claim 2, further comprising grinding the sacrificial layer and forming a flat top surface of the sacrificial layer before removing the portion of the sacrificial layer and the portion of the insulating stack.

5. The manufacturing method according to claim 2, further comprising removing a remaining portion of the sacrificial layer after exposing the first top surface.

6. The manufacturing method according to claim 1, further comprising removing a portion of the semiconductor stack and a portion of the insulating stack to form a plurality of the light-emitting devices.

7. The manufacturing method according to claim 1, before forming the electrode further comprising:
forming a protective layer covering the semiconductor stack; and
forming an opening in the protective layer;
wherein the electrode is filled in the opening and electrically connected to the semiconductor stack.

8. The manufacturing method according to claim 7, further comprising forming a contact layer on the semiconductor stack, wherein the protective layer covers the contact layer and the opening exposes the contact layer.

9. The manufacturing method according to claim 1, wherein a level difference between the first top surface and the second top surface is less than 0.5 μm.

10. A light-emitting device, comprising:
a semiconductor stack;
an electrode formed on the semiconductor stack, comprising a first top surface and a side surface;
an insulating stack covering the semiconductor stack and the side surface, comprising a plurality of first sub-layers with a first refractive index and a plurality of second sub-layers with a second refractive index alternately stacked; and
an electrode pad formed on the insulating stack, connecting to the first top surface;
wherein the insulating stack comprises a second top surface surrounding the first top surface and having a level lower than or equal to that of the first top surface.

11. The light-emitting device according to claim 10, wherein a level difference between the first top surface and the second top surface is less than 0.5 μm.

12. The light-emitting device according to claim 10, wherein:
the semiconductor stack comprises a first semiconductor layer and a mesa on the first semiconductor layer, the mesa includes a second semiconductor layer and the first semiconductor layer comprises an exposed region not covered by the mesa;
the electrode is formed on the exposed region and has a thickness greater than a height of the mesa.

13. The light-emitting device according to claim 10, wherein:
the semiconductor stack comprises a first semiconductor layer and a mesa on the first semiconductor layer, the mesa comprises a second semiconductor layer and the first semiconductor layer comprises an exposed region not covered by the mesa;
the electrode comprises a first electrode on the exposed region and a second electrode on the mesa, and the thickness of the first electrode is greater than the thickness of the second electrode.

14. The light-emitting device according to claim 13, wherein a level difference between a top surface of the first electrode and a top surface of the second electrode is less than 0.5 μm.

15. The light-emitting device according to claim 10, further comprising a protective layer covering the semiconductor stack;
wherein the protective layer comprises an opening and the electrode is filled in the opening and electrically connected to the semiconductor stack.

16. The light-emitting device according to claim 15, further comprising a contact layer under the protective layer;
wherein the opening is formed on the contact layer and the electrode is connected to the contact layer.

17. The light-emitting device according to claim 10, further comprising a covering layer formed on the insulating stack;
wherein the covering layer comprises a third top surface which has a level lower than or equal to that of the second top surface.

18. The light-emitting device according to claim 10, wherein the electrode pad is formed on the third top surface.

19. The light-emitting device according to claim 10, wherein the electrode pad covers and contacts the second top surface.

20. The light-emitting device according to claim 10, wherein each of the first sub-layers and the second sub-layers comprises a cross-section, and the second top surface comprises the cross-sections.
